(19) United States
(12) Patent Application Publication
(10) Pub. No.: US 2025/0006616 A1
(43) Pub. Date: Jan. 2, 2025

(54) HYBRID METALLIZATION SURFACES FOR INTEGRATED CIRCUIT PACKAGES

(71) Applicant: Intel Corporation, Santa Clara, CA (US)

(72) Inventors: Suddhasattwa Nad, Chandler, AZ (US); Kristof Darmawikarta, Chandler, AZ (US); Jason Steill, Phoenix, AZ (US); Srinivas Pietambaram, Chandler, AZ (US); Marcel Wall, Phoenix, AZ (US)

(73) Assignee: Intel Corporation, Santa Clara, CA (US)

(21) Appl. No.: 18/216,521

(22) Filed: Jun. 29, 2023

(51) Int. Cl. H01L 23/498; H01L 21/48; H01L 23/00; H01L 25/065; H01L 25/18; H10B 80/00

(52) U.S. Cl. CPC H01L 23/49838; H01L 21/4846; H01L 24/32; H01L 24/83; H01L 25/0652; H01L 25/18; H10B 80/00; H01L 23/49894; H01L 24/20; H01L 2224/211; H01L 2224/32227; H01L 2224/83031; H01L 2224/83447

(57) ABSTRACT

IC die package with hybrid metallization surfaces. Routing metallization features have lower surface roughness for reduced high-frequency signal transmission losses while IC die attach metallization features have higher surface roughness for greater adhesion. Routing and die attach features may be formed within a same package metallization level, for example with a plating process. An insulator material may be formed over the surface of the metallization features, for example with a dry film lamination process. Optionally, an interface material may be deposited upon at least the routing features to enhance adhesion of the insulator material to metallization surfaces of low roughness. An opening in the insulator material may be formed to expose a surface of a die attach feature. The exposed surface may be selectively roughened, and an IC die attached to the roughened surface.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical contacts suitable for further connecting to a host component, such as a printed circuit board (PCB).

Next generation multi-chip packaging (MCP) demands greater interconnect density to support evolving disaggregated IC systems-in-package and/or bandwidth-intensive applications. In a high bandwidth architecture, for example, multiple IC dies or chips assembled on a package may need to be electrically interconnected through fine routing layers that include lines (i.e., traces) embedded within an interconnect level of the package at a density of at least 250 trace/mm. Higher speed I/O data transfer is also important for next generation interconnects (e.g., SERDES) that are to exceed 28 GHz. Such interconnects need to operate with low signal losses. At higher frequencies, signal transfer becomes more sensitive to the surface of the interconnect metallization features (e.g., lines or traces), a phenomena known as the “skin effect.” For example, at a 1 MHz signal transmission frequency, skin depth is about 66 μm. However, at 28 GHz the skin depth is around 400 nm.

For package substrates, the need for greater interconnect trace density compounded with the need to reduce trace roughness is demanding new approaches and/or architectures to replace conventions that have proven limited to lower line metallization densities and signal transmission frequencies. For MCP, IC dies may be attached to a package substrate comprising metallization traces, for example by means of a die backside film (DBF). The challenges of reducing trace roughness may conflict with such die attach processes resulting in expensive processes that increase package device cost.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIG. 1 is a flow diagram illustrating methods of fabricating an IC device package comprising hybrid metallization features having different surface roughness, in accordance with some embodiments;

FIGS. 2A, 3A, 3A, 4A, 5A, and 6A illustrate cross-sectional views through an IC device package as selected operations of an IC device package fabrication process is performed, in accordance with some embodiments;

FIGS. 2B, 3B, 3B, 4B, 5B, and 6B illustrate cross-sectional views through an IC device package as selected operations of an IC device package fabrication process is performed, in accordance with some alternative embodiments;

FIG. 7 illustrates a system including an MCP with hybrid metallization features interconnecting IC die, in accordance with some embodiments;

FIG. 8 illustrates a mobile computing platform and a data server machine employing package routing with hybrid metallization surfaces, in accordance with embodiments; and

FIG. 9 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

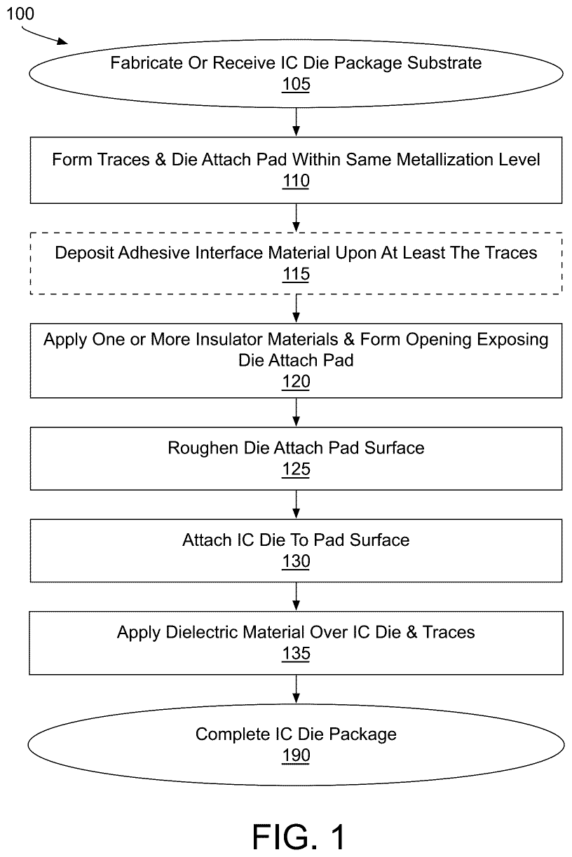

FIG. 1 is a flow diagram illustrating methods 100 for fabricating an IC device package to include metallization features with hybrid surfaces. According to methods 100, within one level of metallization, some metallization features (e.g., routing lines) have low surface roughness while other metallization features (e.g., die attach pads) have a high surface roughness. Metallization features with low surface roughness (e.g., <30 nm average roughness) ensure low insertion loss for the transmission of high frequency (e.g., 28 GHz) data signals. Metallization features with high surface roughness (e.g., >50 nm average roughness) ensure strong adhesion, for example to IC dies attached to the metallization features. As described further below, in some embodiments where a package insulator material, such as an organic dielectric material, may suffer delamination from metallization features of low surface roughness, an interface material, such as an inorganic dielectric material, may be formed upon metallization features of low surface roughness prior to forming the package insulator material. In some further embodiments also described below, the interface material may be absent from metallization features of high surface roughness where the interface material is unnecessary or detrimental.

Methods 100 leverage semi-additive processing (SAP) techniques. According to some embodiments, routing metallization features may comprise lines or traces that interconnect multiple IC die co-assembled with the package. The routing metallization features may be electrically insulated from each other as well as from adjacent die attached features with one or more insulator materials, such as organic dielectric build-up materials. While such materials often adhere poorly to metallization features of low surface roughness, the addition of an intervening layer of interface material can mitigate risk of package film delamination. With low surface roughness, line metallization fabricated according to methods 100 may transmit high-frequency data signals with greater integrity. Accordingly, the IC device package fabrication methods 100 may be advantageous for 2D, 2.5D, and 3D MCP packages.

Hybrid metallization surfaces fabricated according to methods 100 may include die attach metallization surfaces that are treated (e.g., mechanically or chemically) to have high surface roughness. The treatment(s) is (are) advantageously performed selectively to die attach features while routing metallization features are protected from the treatment, for example by an overlying package insulator that may be retained as a permanent package film. In the absence of any roughening treatment of the routing metallization, an interface material suitable for forming strong bonds with insulator material may be deposited to improve adhesion of routing metallization with package insulator material.

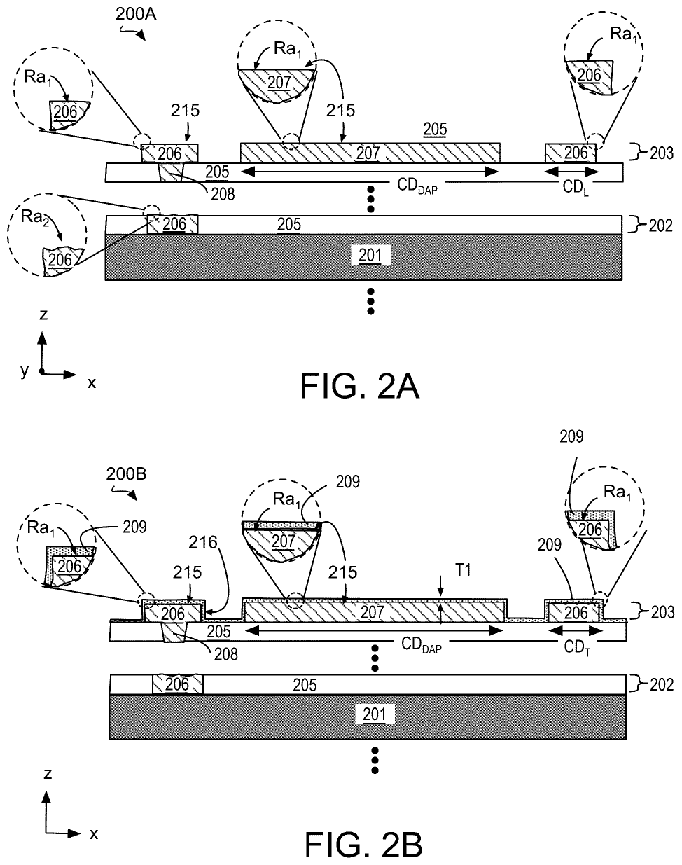

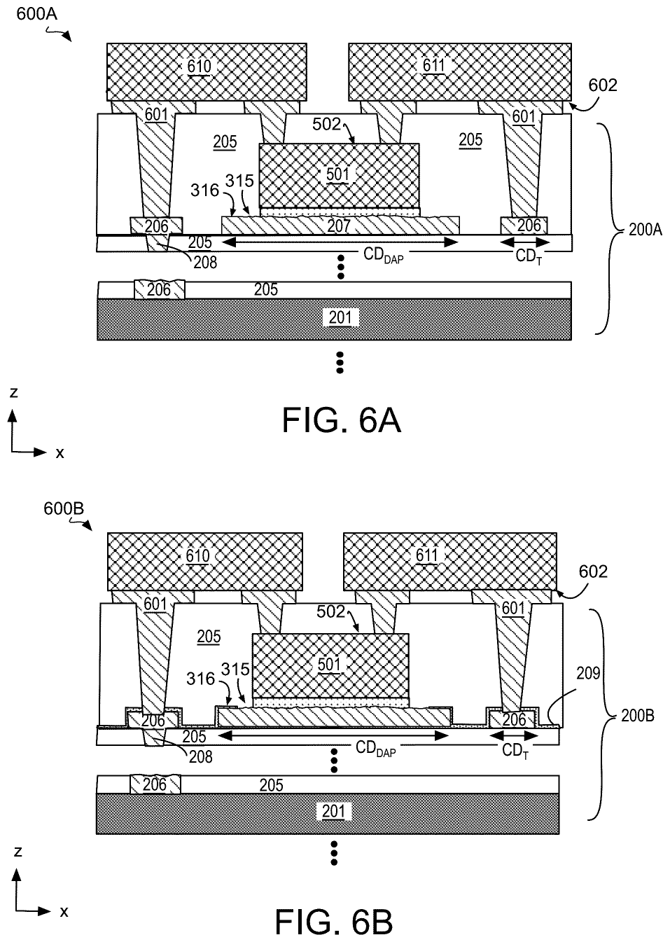

Methods 100 may be repeated any number of times to build up an interconnect structure comprising any number of levels of metallization features comprising multiple material layers. FIG. 2A-6A illustrate cross-sectional views through a first exemplary IC device package as the blocks in methods 100 are performed, in accordance with some embodiments. FIG. 2B-6B illustrate cross-sectional views through a second exemplary IC device package as the blocks in methods 100 are performed, in accordance with some alternative embodiments. In FIGS. 2A-6A and FIGS. 2B-6B, exemplary metallization structures are illustrated on a “die-side” of an IC device package. However, the same processing may be practiced on a “land-side” of an IC device package. The processing may therefore be symmetrical on both die-side and land-side of an IC device package, or not.

Referring first to FIG. 1, methods 100 begin at input 105 where a workpiece including a package substrate suitable for SAP is either fabricated or received as a preform. The package substrate fabricated or received at input 105 may have any architecture as embodiments are not limited in this context. Generally, the package substrate includes at least some electrically insulative (i.e., insulator) material, and may further include one or more metallization levels embedded within the insulator. Each metallization level may include any number of substantially co-planar metallization features. In some embodiments, the workpiece fabricated or received at input 105 is substantially planar and dimensioned in thickness and lateral area to be a suitable support for panelized processing of multiple packages arrayed over the substrate (i.e., WLP). As further described below, the substrate may comprise one or more material layers. The various material layers of a substrate may be retained within a final singulated package or separated from a final package as part of a sacrificial carrier.

The package substrate fabricated or received at input 105 may be “cored” or “coreless.” In the absence of a core, a package substrate may rely on a sacrificial carrier to mechanically support the package build-up materials. Methods 100 continue at block 110 where both a signal routing trace and an IC die attach feature (e.g., “pad”) are formed within a single (same) metallization level. The die attach feature is to provide a land to which an IC die will be subsequently attached.

In the example further illustrated in FIG. 2A, package substrate 200A comprises a “core” 201. Core 201 may be any preform comprising any material with mechanical rigidity and/or stiffness sufficient to serve as a platform for building up levels of package routing metallization. A single-side build-up may be performed on the front (die) side of core 201, or, as denoted by ellipses in FIG. 2A, a double-side build-up may be practiced concurrently on a front (die) side and a back (land) side of the core 201.

Package metallization features are embedded within one or more layers of package insulator material 205. In some exemplary embodiments, package insulator material 205 comprises an organic dielectric material (e.g., comprising one or more polymers). In some embodiments, package insulator material 205 comprises an epoxy resin, phenolic-glass, or a resinous film such as the GX-series films commercially available from Ajinomoto Fine-Techno Co., Inc.), which may be advantageously applied as a dry film laminate. Exemplary epoxy resins include an acrylate of novolac such as epoxy phenol novolacs (EPN), or epoxy cresol novolacs (ECN). In some specific examples, package insulator material 205 is a bisphenol-A epoxy resin, for example including epichlorohydrin. In other examples, package insulator material 205 includes bisphenol-F epoxy resin (with epichlorohydrin). In other examples, package insulator material 205 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package insulator material 205 includes glycidylamine epoxy resin, such as triglycidyl-p-aminophenol (functionality 3) and N,N,N′,N′-tetraglycidyl-bis-(4-aminophenyl)-methane (functionality 4). Although such polymeric materials may decompose at high processing temperatures (e.g., >400° C.), these materials may offer many advantages associated with SAP techniques.

Within package substrate 200A, each metallization level 202, 203 comprises a line metallization feature 206. Between two nearest metallization levels, routing metallization comprises a via metallization feature 208, for example coupling line metallization features of different levels. Within upper metallization level 203, line metallization feature 206 may have any minimal lateral dimension CDL, but in some exemplary embodiments where a line metallization level has a line density of at least 250 trace/mm, CDL is 2 μm, or less. Lower metallization level 202 may have a different (e.g., lower) line density than upper metallization level 202.

For highest line density, line metallization feature 206 is advantageously protected from dimensional loss, for example during seed layer patterning and/or other processing performed in preparation for depositing a layer of insulator material upon exposed surfaces of line metallization feature 206. In the expanded view of FIG. 2A, line metallization 206 is illustrated as having low average roughness Ra₁, at least on a top (die-side) surface 215. In exemplary embodiments, average roughness Raj is less than 100 nm, advantageously less than 50 nm, and more advantageously less than 30 nm. As used herein, average roughness (or center line average) is as described in ASME B46.1. Average roughness is the arithmetic average of the absolute values of profile height deviations from a mean line that is recorded for an evaluation length. Average roughness may be measured, for example, with a profilometer comprising a stylus that is traversed over a surface. For line metallization 206 having a longitudinal length in a first dimension (e.g., coincident with y-axis), average roughness may be measured over a distance roughly 60-70% of the longitudinal line length while remaining at about a centerline of a transverse width of line metallization 206 that is a dimension substantially orthogonal to the first dimension (e.g., coincident with x-axis).

In some embodiments all routing features within a package have substantially the same low surface roughness. In other embodiments, one or more levels of metallization within a package have low surface roughness while one or more other levels of metallization within the package have higher surface roughness. In package substrate 200A, for example, within lower line metallization level 202, a line metallization feature 206 has a higher average surface roughness Ra₂. The higher surface is permissible where a level of line metallization is not to convey high frequency (e.g., exceeding 1 GHz) data signals, but instead includes power routing. Although average surface roughness Ra₂ may vary with implementation, in some examples it is over 50 nm and may be 100 nm, or more.

Within package metallization level 203, there is an IC die attach metallization feature 207 in addition to line metallization feature 206. Die attach metallization feature 207 is substantially co-planar with line metallization feature 206. Die attach metallization feature 207 may have substantially the same composition as line metallization feature 206 and is advantageously fabricated concurrently with the line metallization features that are within the same metallization level. Die attach metallization feature 207 may therefore also have low surface roughness (e.g., average roughness Ra₁). Die attach metallization feature 207 may be referred to as a die attach “pad” as it typically has a rectangular footprint (e.g., within x-y plane) and has a minimal lateral dimension CD_{DAP} that is significantly larger than a minimum line dimensional CDL. Although die attach metallization feature 207 may have any lateral dimensions sufficient to accommodate an arbitrarily large/small IC die, in exemplary embodiments die attach pad dimension CD_{DAP} is at least 1 mm and may be 10 mm, or more. For die attach pad 207, average roughness may be measured in a first dimension (e.g., coincident with y-axis) over a distance roughly 60-70% of the length CD_{DAP} while remaining at about a centerline of a width of die attach pad 207 that is in a dimension substantially orthogonal to the first dimension (e.g., coincident with x-axis).

Line metallization feature 206 and die attach metallization feature 207 (as well as via metallization feature 208) may be formed with an additive or semi-additive process, for example. In some embodiments, line metallization feature 206 and die attach metallization feature 207 comprise one or more layers of predominantly copper. For example, line metallization feature 206 and die attach metallization feature 207 may include a first layer of Cu that may have been deposited with a first deposition process (e.g., sputter, electroless plating, etc.), and a second layer of Cu that may have been deposited with a second deposition process (e.g., electrolytic plating). The first layer of Cu may therefore function as a seed layer. Since such material layers are both predominantly Cu, separate layers are not illustrated in FIG. 2A.

Returning to FIG. 1, methods 100 continue with an optional block where an interface material is deposited over at least the trace or line metallization features. The interface material may be formed, for example, directly on at least a top surface of metallization features. The interface material may have any composition suitable for promoting adhesion of a subsequently deposited package insulator material that might otherwise suffer from low adhesion to a metallization surface of low average roughness.

In some exemplary embodiments, block 115 comprises deposition of an inorganic dielectric material. Such a deposition may comprise one or more of a sputtering (physical vapor deposition) process, a chemical vapor deposition (CVD) process, a plasma enhanced CVD (PECVD) process, or the like. For low temperature (e.g., <250° C.) embodiments advantageous where an underlying package insulator comprises organic material that might decompose at higher temperatures, PVD is practiced at block 115.

In other embodiments, block 115 comprises a nitrogen treatment (i.e., nitriding) metallization feature surfaces to introduce nitrogen to the exposed surfaces or into a none-zero surface layer thickness. With treatment, nitrogen may advantageously react with one or more metals present at the surface of the metallization feature, forming a metal nitride compound. For example, in some embodiments where the metallization feature comprises predominantly copper, a copper nitride compound, such as Cu₃N, is formed on the exposed surfaces of the metallization features. In some embodiments, a nitrogen treatment comprises a plasma nitridation where a precursor gas comprising nitrogen is energized into a plasma, for example with an RF or microwave power source (e.g., generator, magnetron, etc.) In exemplary embodiments, the precursor gas is NH₃. Other precursors, such as, but not limited to, N₂O or N₂ are also possible.

FIG. 2B illustrates an exemplary package substrate 200B, which has all the features of package substrate 200A (FIG. 2A) with the addition of an interface material 209. Interface material 209 is in direct contact with at least top surface 215 of metallization feature within metallization level 203. Interface material 209 may, for example be present only within metallization levels of a package that include metallization features of low surface roughness. In FIG. 2B, interface material 209 is absent from metallization level 202. Interface material 209 is in direct contact with a surface of package insulator material 205. In the illustrated examples, interface material 209 spans spaces between line metallization feature 206 and die attach metallization feature 207. The presence of interface material 209 on underlying insulator material 205 is indicative of interface material 209 having been deposited, for example by PVD, as opposed to being a product of a chemical reaction with metallization features 206, 207 (in which case there would be interface material 209 only where there is underlying metallization).

In the example of FIG. 2B, interface material 209 is asymmetrically deposited on one side of core 201. However, in alternative embodiments interface material 209 may also be deposited on two sides of core 201. As shown, interface material 209 is on both on top surface 215 and a sidewall surface 216 of line metallization feature 206 and die attach metallization feature 207. Interface material 209 has a non-zero thickness TI that is advantageously less than 1 μm, more advantageously less than 100 nm, and potentially as thin as 2-10 nm. Notably, interface material 209 need not be a continuous film as illustrated and may instead be discontinuous, for example with pinholes and/or islands of material that have not completely coalesced into a continuous film layer. In FIG. 2B, interface material 209 is substantially conformal with thickness TI being substantially the same between top surface 215 and sidewall surface 216. Alternatively, interface material 209 may instead be non-conformal with thickness TI significantly greater on the top surface 215 than on sidewall surface 216 (e.g., as measured in a direction normal to sidewall surface 216).

In exemplary embodiments, interface material 209 is an inorganic dielectric material although organic dielectrics are also possible. In some embodiments, interface material 209 is an inorganic dielectric material comprising nitrogen. In further embodiments, interface material 209 also comprises silicon and may, for example, be predominantly silicon and nitrogen (e.g., SiN). In other embodiments where interface material 209 is a reaction product of metallization features, interface material 209 may again comprises nitrogen and one or more metals (e.g., Cu) that are present within line metallization feature 206 and die attach metallization feature 207. In addition to nitrogen, interface material 209 may further comprise other constituents, such as oxygen and/or carbon. In some embodiments, interface material 209 is SION, SiO, or SiCN, which may have been deposited by PVD, for example.

Returning to FIG. 1, methods 100 continue at block 120 where a package insulator material is formed over the metallization features and an opening is formed in the insulator to expose the die attach feature. In exemplary embodiments, an organic dielectric material, such as any of the materials described above as suitable package insulator materials may be applied by liquid dispense followed by a curing process, or applied as a dry film laminate, for example. Additional levels of metallization and insulator material may be formed before an opening or cavity is formed to expose an underlying die attach feature. An opening or cavity is then formed through one or more layers of insulator material to expose die attach metallization in preparation for IC die assembly. Depending on insulator material composition and dimensions of the cavity to be formed, package insulator material may be mechanically drilled, laser ablated, or etched with wet or dry (plasma) etch processes.

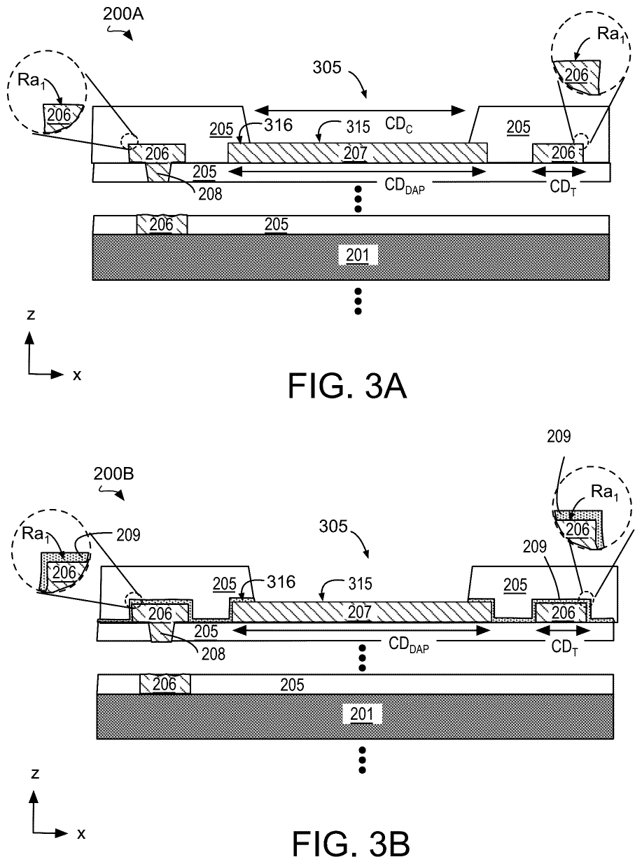

In the embodiment further illustrated in FIG. 3A, a die cavity 305 within insulator material 205 has been formed, for example with a laser ablation process. Cavity 305 is dimensioned to accommodate subsequent attachment of an IC die to a center portion 315 of die attach metallization feature 207 exposed at the bottom of cavity 305. In exemplary embodiments, cavity 305 has a lateral minimum dimension CD_{C} that is sufficiently smaller than lateral pad dimension CD_{DAP} to ensure insulator material 205 remains over a perimeter portion 316 of die attach metallization feature 307, which surrounds center portion 315.

FIG. 3B illustrates exemplary embodiments including interface material 209, which are advantageous where insulator material 205 would otherwise have poor adhesion to metallization line feature 206 and/or die attach metallization feature 207. With insulator material 205 in contact with interface material 209, greater chemical bonding may occur across the interface of the two materials. As further shown in FIG. 3B, interface material 209 may be removed during formation of cavity 305 such that there is no interface material 209 remaining on center die attach metallization portion 315. For example, a laser ablation process may be unselective to interface material 209 and/or interface material 209 may be of insufficient thickness to survive any process employed in the formation of cavity 305. Removal of interface material 209 from within cavity 305 may be advantageous, for example where interface material 209 is not a suitable for die attach. For embodiments where interface material 209 would be suitable for die attach, its removal may merely be an incidental artifact of the formation of cavity 305.

Returning to FIG. 1, methods 100 continue at block 125 where the exposed surface of a die attach metallization feature is roughened through one or more chemical and/or mechanical processes. In some exemplary embodiments, a wet chemical etch is performed at block 125. For example, where a die attach metallization feature is predominantly Cu, a Cu etchant solution may be introduced to the exposed surface. The etchant solution increases surface roughness, for example by 2-5 times, or more. In alternative embodiments, an ion milling or sputter process may be practiced to similarly increase surface roughness.

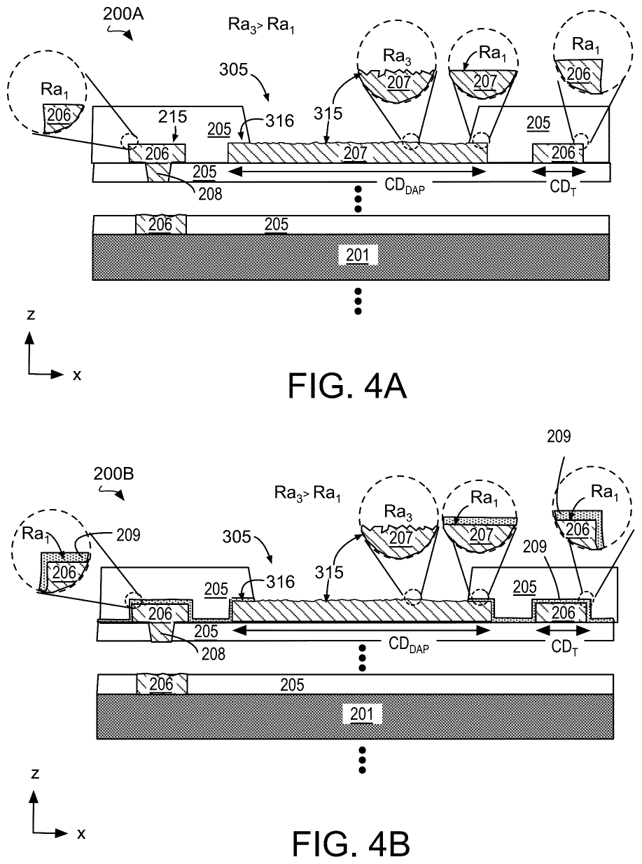

In the example illustrated in FIG. 4A, the center portion 315 of die attach metallization feature 207 exposed within cavity 305 is roughened to surface roughness (e.g., average roughness of Ra₃) that is greater than that of perimeter portion 316 as well as that of line metallization feature 206, both of which retain their initial surface roughness (e.g., average roughness Ra₁). In exemplary embodiments, average roughness Ra₃ is greater than 50 nm, advantageously more than 100 nm, and may be 200 nm, or more. Hence, in some specific embodiments, where average roughness Raj is less than 50 nm (e.g., 30 nm, or less), average roughness Ra₃ is more than 50 nm (e.g., 70 nm, or more).

In the example illustrated in FIG. 4B, the center portion 315 of die attach metallization feature 207 exposed within cavity 305 has been similarly roughened to a surface roughness (e.g., average roughness of Ra₃) greater than that of perimeter portion 316, which retains the initial surface roughness and remains covered by interface material 209. Average roughness of Ra₃ is accordingly also greater than average roughness Raj of line metallization feature 206.

Methods 100 (FIG. 1) continue at block 130 where one or more IC dies are attached to one or more die attach features. IC dies may be attached one-to-one on corresponding die attach features, or may be attached in many-to-one architecture, as embodiments are not limited in this context. Die attachment at block 130 may entail any techniques known to be suitable. In some exemplary embodiments, block 130 comprises the attachment of an IC die which has a die attach film (DAF) adhered to a surface of the IC die. The DAF is to provide an adhesive bond with a surface of a die attach metallization feature of a package substrate.

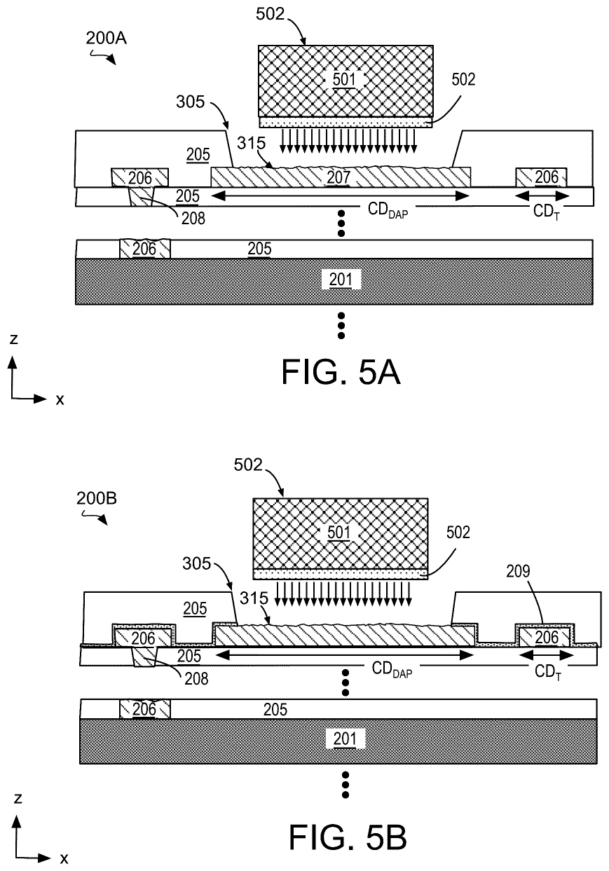

In the examples illustrated in FIGS. 5A and 5B, a DAF 502 is adhered to a back side of an IC die 501 and so may be referred to as a DBF. A device (front) side 502 of IC die 501 faces opposite package substrate 200A, 200B. IC die 501 is positioned within cavity 305 and DAF 502 is brought into direct contact with a center portion 315 of die attach metallization feature 207 exposed within cavity 305. DAF 502 may be any adhesive film known to be suitable for IC die attachment.

In some exemplary embodiments, IC die 501 is a “passive” die and lacks any FETs fabricated within a device layer proximal to device side 502. Such a passive die may merely include interconnect routing levels. These interconnect routing levels may, for example, convey electrical communication signals between other IC dies and therefore referred to as a “bridge” die.

Alternatively, IC die 501 may be an “active” die including FETs fabricated within a device layer proximal to device side 502. For either passive or active embodiments, IC die 501 may include devices such as resistors, capacitors, or inductors (not depicted). IC die 501 may be a fully functional ASIC, or may be a chiplet or tiles that has more limited functionality that supplements the function of one or more other IC dies within a multi-chip package. A chiplet or tile may, for example, be any of a wireless radio circuit, microprocessor core, electronic memory circuit, floating point gate array (FPGA), power management and/or power supply circuit, or include a MEMS device. For active embodiments, IC die 501 may comprise any of circuitry microprocessor circuitry, graphics processing circuitry, or heterogeneous processing circuitry, etc. Microprocessor circuitry may be operable, for example, to execute a real-time operative system (RTOS). In some further embodiments, IC die 501 is operable to execute one or more layers of a software stack that controls radio (wireless) functions. In other embodiments, IC die 501 includes electronic memory circuitry, such as, but not limited to, dynamic random-access memory (DRAM).

Returning to FIG. 1, methods 100 continue at block 135 where additional package insulator material is applied over the IC die(s) attached at block 130, and over adjacent portions of the package substate. The insulator material may then be planarized and any number of additional metallization levels may be built up to complete the package structures at output 190. Any of the processes and materials described above may be deposited or otherwise applied to further build-up the package substrate in preparation for an assembly of one or more IC die. For exemplary multi-chip package embodiments, one or more additional IC dies are attached to the package substrate to complete a package structure. The additional IC die may, for example, be interconnected to other IC die through routing metallization of the package substrate. A first side of the completed package metallization structure may be interconnected to any number of IC die. A second side of the package substrate may be interconnected to any suitable host component.

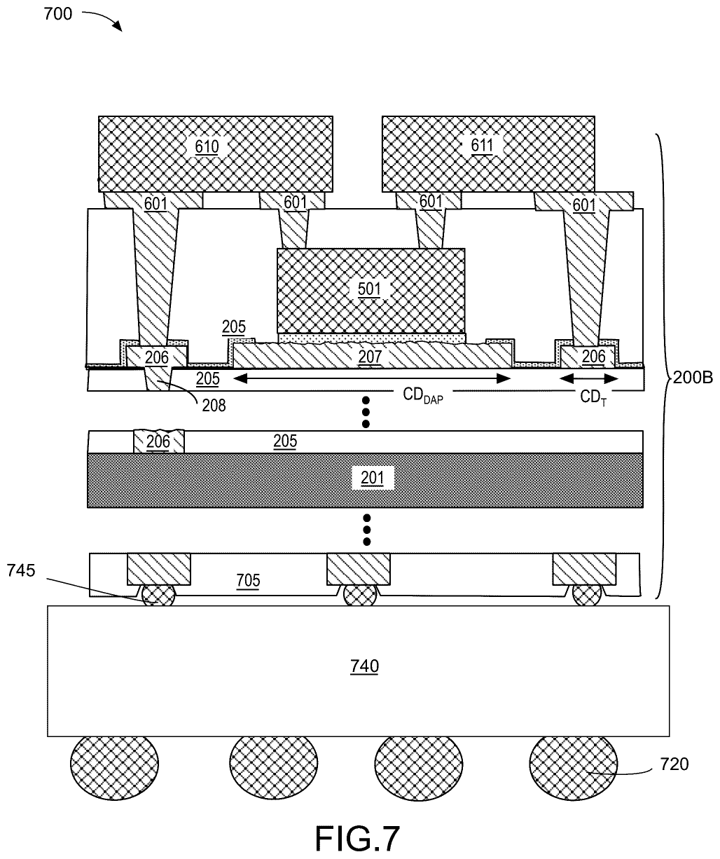

FIGS. 7A and 7B illustrate IC device package structures 600A and 600B, respectively. Package insulator material 205 has been planarized over front side IC die surface 502 and surface via metallization features 601 contact interconnect interfaces of IC die 501. Other surface via metallization features 601 couple with package routing metallization, which may for example route power and/or data signals to an opposite (land) side of the package structures 600A, 600B.

IC die 610 and IC die 611 are attached to surface via metallization features 601, for example by direct bonding or solder interconnects (not depicted). IC die 610 and 611 are illustrated in a flip-chip configuration with device sides 612 facing package substrates 200A, 200B. However, IC die 610 and 611 may instead be in a back-to-face orientation with through-die vias (not depicted) coupled to surface via metallization features 601. Each of IC die 610 and IC die 611 may be a passive die or an active die including FETs fabricated within a device layer proximal to device side 602. For active IC die embodiments, IC dies 610, 611 may each be a fully functional ASIC, or may each be a chiplet or tile that has more limited functionality supplementing the function of one or more other IC dies within a multi-chip package. For active IC die embodiments, each of IC die 610, 611 may comprise any of circuitry microprocessor circuitry, graphics processing circuitry, or heterogeneous processing circuitry, etc. In some exemplary embodiments, IC die 501 is a bridge die with routing metallization that electrically interconnects I/O of IC die 610 to I/O of IC die 611. For some such embodiments, IC die 610 is operable to execute one or more layers of a software stack that controls radio (wireless) functions while IC die 611 includes electronic memory circuitry, such as, but not limited to, DRAM.

FIG. 7 illustrates a system 700 including IC device package structure 600B interconnecting two IC die 610 and 611 (chips or chiplets) to each other through a third IC die 501, in accordance with some embodiments. System 700 may similarly include IC device package structure 600A. Package structure 600B is coupled to a host component 740. Host component 740 may be a PCB or interposer attached to package metallization through any suitable interconnect 745 (e.g., solder). In some exemplary embodiments, a land-side of host component 740 opposite package structure 600B is further processed to receive second level interconnects 720 (e.g., solder). System 700 may further include one or more of overmold (not depicted), a heat spreader (not depicted), and/or an active cooling structure (not depicted).

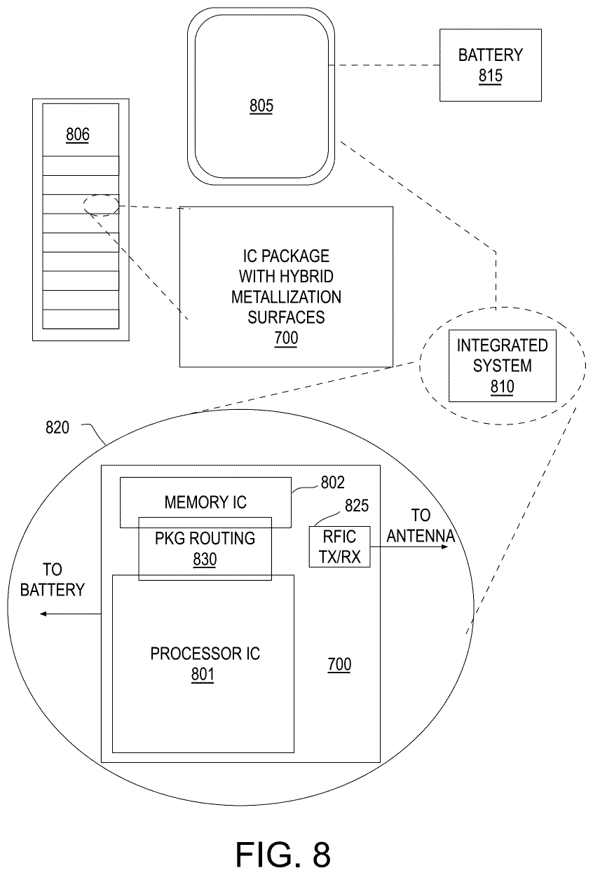

FIG. 8 illustrates a mobile computing platform and a data server machine employing an IC package with hybrid metallization surfaces, for example as described elsewhere herein. The server machine 806 may be any commercial server, for example including any number of high-performance computing platforms disposed within a rack and networked together for electronic data processing, which in the exemplary embodiment includes a MCP. The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), a chip-level or package-level integrated system 810, and a battery 815.

As a system component within the server machine 806, package structure 700 includes a memory IC (e.g., RAM) die 802 and a processor IC (e.g., a microprocessor, a multi-core microprocessor, baseband processor, or the like) die 801 are interconnected through a package routing 830 having a hybrid of both high and low surface roughness within one metallization level, for example substantially as described elsewhere herein. One or more other IC die may also be assembled with package structure 700. For example, a RF (wireless) integrated circuit (RFIC) 825 including a wideband RF (wireless) transmitter and/or receiver (TX/RX) may be further interconnected to package structure 700. Functionally, RFIC 825 may have an output coupled to an antenna to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

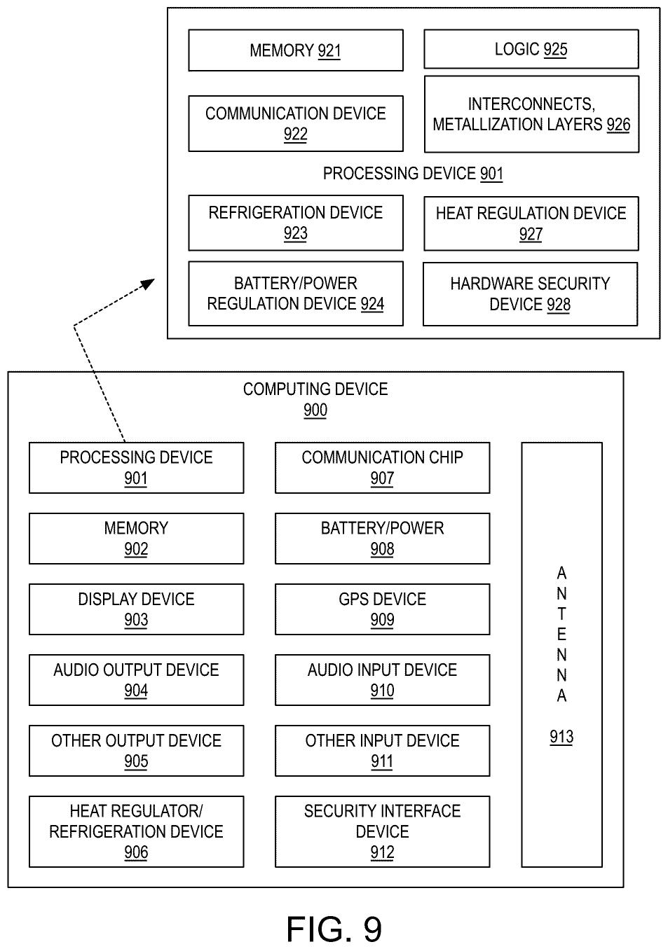

FIG. 9 is a block diagram of a cryogenically cooled computing device 900 in accordance with some embodiments. For example, one or more components of computing device 900 may include any of the devices or structures discussed elsewhere herein. A number of components are illustrated in FIG. 9 as included in computing device 900, but any one or more of these components may be omitted or duplicated, as suitable for the application. In some embodiments, some of the components included in computing device 900 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled.

Computing device 800 may include a processing device 801 (e.g., one or more processing devices). As used herein, the term processing device or processor indicates a device that processes electronic data from registers and/or memory to transform that electronic data into other electronic data that may be stored in registers and/or memory. Processing device 801 may include a memory 821, a communication device 822, a refrigeration/active cooling device 823, a battery/power regulation device 824, logic 1325, interconnects 826, a heat regulation device 827, and a hardware security device 828.

Processing device 801 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 801 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing 801 shares a package with memory 802. This memory may be used as cache memory and may include embedded dynamic random-access memory (eDRAM) or spin transfer torque magnetic random-access memory (STT-M RAM).

Computing device 800 may include a heat regulation/refrigeration device 823. Heat regulation/refrigeration device 823 may maintain processing device 801 (and/or other components of computing device 800) at a predetermined low temperature during operation. This predetermined low temperature may be any temperature discussed elsewhere herein.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1307 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1307 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 1300 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a global positioning system (GPS) device 809 (or corresponding interface circuitry, as discussed above). GPS device 809 may be in communication with a satellite-based system and may receive a location of computing device 800, as known in the art.

Computing device 800 may include another output device 805 (or corresponding interface circuitry, as discussed above). Examples include an audio codec, a video codec, a printer, a wired or wireless transmitter for providing information to other devices, or an additional storage device.

Computing device 800 may include another input device 811 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, managing access lists, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples, an integrated circuit (IC) device package comprises a substrate comprising one or more metallization levels. One of the metallization levels comprises a metallization line with a top surface of a first roughness and a metallization pad with a top surface of a second roughness, greater than the first roughness. An IC die is coupled to the top surface of the metallization pad, and an insulator material is over the top surface of the metallization line.

In second examples, for any of the first examples the top surface of the metallization line has an average roughness below 100 nm, and the top surface of the metallization pad has an average roughness at least twice that of the top surface of the metallization line.

In third examples, for any of the first through second examples average roughness is the arithmetic average of the absolute values of profile height deviations from a mean line that is recorded for an evaluation length of the top surface.

In fourth examples, for any of the third examples the metallization line has a longitudinal length in a first dimension, and the average roughness is measured over a distance of at least 60% of the longitudinal length.

In fifth examples, for any of the first through fourth examples the insulator material is over a perimeter of the metallization pad and is laterally adjacent to the top surface with the second roughness, and the perimeter of the metallization pad comprises a top surface of less than the second roughness.

In sixth examples, for any of the fifth examples the top surface of the perimeter of the metallization pad has the first roughness.

In seventh examples, for any of the first through sixth examples the insulator material is an organic dielectric material comprising one or more organic polymer and the IC device package further comprises an interface material layer between the top surface of the metallization line and the organic dielectric material, and wherein the interface material layer is absent from between the metallization pad and the IC device.

In eighth examples, for any of the seventh examples the interface material layer is an inorganic dielectric material.

In ninth examples, for any of the eighth examples the metallization line and metallization pad each comprise predominantly Cu, the inorganic dielectric material comprises nitrogen, and the inorganic dielectric material is in direct contact with the metallization line.

In tenth examples, for any of the seventh through ninth examples the organic dielectric material is over a perimeter of the metallization pad and is adjacent to the top surface with the second roughness. The interface material layer is in contact with the perimeter of the metallization pad.

In eleventh examples, a system comprises a first integrated circuit (IC) die, a second IC die, and a third IC die underlying at least one of the first IC die or the second IC die and comprising a first side that is interconnected to both the first IC die and the second IC die. The third IC die comprises a second side, opposite the first side, that is attached to a top surface of a metallization pad. The metallization pad is substantially co-planar with an adjacent metallization line, the top surface of the metallization line has a first roughness, and the top surface of the metallization pad has a second roughness, greater than the first roughness.

In twelfth examples, for any of the eleventh examples the top surface of the metallization line has an average roughness below 30 nm and the top surface of the metallization pad has an average roughness over 50 nm.

In thirteenth examples, for any of the eleventh through twelfth examples the third IC die electrically interconnects the first IC die to the second IC die, and an organic dielectric material is between the top surface of the metallization line and at least one of the first IC die or the second IC die.

In fourteenth examples, for any of the thirteenth examples the organic dielectric material is over a perimeter of the metallization pad and is adjacent to the top surface with the second roughness; and wherein the perimeter of the metallization pad comprises a top surface with the first roughness.

In fifteenth examples, for any of the thirteenth through fourteenth examples the system further comprising an interface material layer between the top surface of the metallization line and the organic dielectric material, wherein the interface material layer is absent from between the metallization pad and the IC die.

In sixteenth examples, for any of the fifteenth examples the interface material layer comprises predominantly silicon and nitrogen.

In seventeenth examples, a method of fabricating an integrated circuit (IC) device package, the method comprises receiving a substrate comprising a metallization level comprising a metallization pad with a first top surface of a first roughness and, laterally adjacent to the metallization pad, a metallization line with a second top surface of substantially the first roughness. The method comprises depositing an insulator material over the metallization level. The method comprises exposing a portion of the first top surface by forming an opening through the insulator material while retaining the insulator material over the second top surface. The method comprises roughening the portion of the first top surface to a second roughness, and attaching an IC die to the portion of the first top surface after the roughening.

In eighteenth examples, for any of the seventeenth examples a side of the IC die is in contact with a die-attach-film (DAF) and attaching the IC die comprises contacting the DAF to the portion of the first top surface.

In nineteenth examples, for any of the seventeenth through eighteenth examples the insulator material is an organic dielectric material comprising one or more organic polymers. The method further comprises depositing an interface material layer over the metallization level prior to depositing the organic dielectric material.

In twentieth examples, for any of the nineteenth examples depositing the interface material layer comprises physical vapor deposition of an inorganic dielectric material comprising nitrogen.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An integrated circuit (IC) device package, comprising:
a substrate comprising one or more metallization levels, wherein one of the metallization levels comprises:
a metallization line with a top surface of a first roughness; and
a metallization pad with a top surface with a second roughness, greater than the first roughness;
an IC die coupled to the top surface of the metallization pad; and
an insulator material over the top surface of the metallization line.

2. The IC device package of claim 1, wherein:
the top surface of the metallization line has an average roughness below 100 nm; and
the top surface of the metallization pad has an average roughness at least twice that of the top surface of the metallization line.

3. The IC device package of claim 1, wherein average roughness is the arithmetic average of the absolute values of profile height deviations from a mean line that is recorded for an evaluation length of the top surface.

4. The IC device package of claim 3, wherein
the metallization line has a longitudinal length in a first dimension; and
average roughness is measured over a distance of at least 60% of the longitudinal length.

5. The IC device package of claim 1, wherein:
the insulator material is over a perimeter of the metallization pad and is laterally adjacent to the top surface with the second roughness; and
the perimeter of the metallization pad comprises a top surface of less than the second roughness.

6. The IC device package of claim 5, wherein the top surface of the perimeter of the metallization pad has the first roughness.

7. The IC device package of claim 1, wherein the insulator material is an organic dielectric material comprising one or more organic polymer and the IC device package further comprises an interface material layer between the top surface of the metallization line and the organic dielectric material, and wherein the interface material layer is absent from between the metallization pad and the IC die.

8. The IC device package of claim 7, wherein the interface material layer is an inorganic dielectric material.

9. The IC device package of claim 8, wherein the metallization line and metallization pad each comprises predominantly Cu, the inorganic dielectric material comprises nitrogen, and the inorganic dielectric material is in direct contact with the metallization line.

10. The IC device package of claim 7, wherein the organic dielectric material is over a perimeter of the metallization pad and is adjacent to the top surface with the second roughness; and wherein the interface material layer is in contact with the perimeter of the metallization pad.

11. A system comprising:
a first integrated circuit (IC) die;
a second IC die; and
a third IC die underlying at least one of the first IC die or the second IC die, and comprising a first side that is interconnected to both the first IC die and the second IC die and a second side, opposite the first side, that is attached to a top surface of a metallization pad, wherein:
the metallization pad is substantially co-planar with an adjacent metallization line; the top surface of the metallization line has a first roughness; and
the top surface of the metallization pad has a second roughness, greater than the first roughness.

12. The system of claim 11, wherein:
the top surface of the metallization line has an average roughness below 30 nm; and
the top surface of the metallization pad has an average roughness over 50 nm.

13. The system of claim 11, wherein:
the third IC die electrically interconnects the first IC die to the second IC die; and
an organic dielectric material is between the top surface of the metallization line and at least one of the first IC die or the second IC die.

14. The system of claim 13, wherein the organic dielectric material is over a perimeter of the metallization pad and is adjacent to the top surface with the second roughness; and wherein the perimeter of the metallization pad comprises a top surface with the first roughness.

15. The system of claim 13, further comprising an interface material layer between the top surface of the metallization line and the organic dielectric material, wherein the interface material layer is absent from between the metallization pad and the IC die.

16. The system of claim 15, wherein the interface material layer comprises predominantly silicon and nitrogen.

17. A method of fabricating an integrated circuit (IC) device package, the method comprising:
receiving a substrate comprising a metallization level comprising a metallization pad with a first top surface of a first roughness and, laterally adjacent to the metallization pad, a metallization line with a second top surface of substantially the first roughness;
depositing an insulator material over the metallization level;
exposing a portion of the first top surface by forming an opening through the insulator material while retaining the insulator material over the second top surface;
roughening the portion of the first top surface to a second roughness; and
attaching an IC die to the portion of the first top surface after the roughening.

18. The method of claim 17, wherein a side of the IC die is in contact with a die-attach-film (DAF) and attaching the IC die comprises contacting the DAF to the portion of the first top surface.

19. The method of claim 17, wherein the insulator material is an organic dielectric material comprising one or more organic polymers, and wherein the method further comprises depositing an interface material layer over the metallization level prior to depositing the organic dielectric material.

20. The method of claim 19, wherein depositing the interface material layer comprises physical vapor deposition of an inorganic dielectric material comprising nitrogen.
